(19) United States
(12) Patent Application Publication
(10) Pub. No.: US 2026/0322030 A1
(43) Pub. Date: Oct. 15, 2026

(54) SELF-COOLING CONNECTOR

(71) Applicant: Changchun Jetty Automotive Technology Co., Ltd., Changchun, Jilin Province (CN)

(72) Inventor: Chao WANG, Changchun (CN)

(21) Appl. No.: 19/483,572

(22) PCT Filed: May 11, 2024
(86) PCT No.: PCT/CN2024/092642

§ 371 Date: Nov. 11, 2025

(30) Foreign Application Priority Data
May 11, 2023 (CN) 202310527620.X

(51) Int. Cl. H01R 13/533

(52) U.S. Cl. CPC H01R 13/533

(57) ABSTRACT

Disclosed is a self-cooling connector, including a connector housing, a terminal and a conductor which are at least partially disposed in the connector housing, and a cooling device disposed in the connector housing. The cooling device includes a rigid shell, and a pressure-applying member and a cooling medium which are disposed in the rigid shell.

### RELATED APPLICATION

The present disclosure claims priority to Chinese Invention Patent Application No. 202310527620.X filed on May 11, 2023, which is hereby incorporated by reference in its entirety.

### TECHNICAL FIELD

The present disclosure relates to the field of electrical connections, and particularly to a self-cooling connector.

### BACKGROUND

In the field of electrical connections, wiring harnesses are universally used to connect various electrical appliances. A wiring harness includes a wire that conducts electric current and connectors at its ends, and electrical connections are achieved by plugging the connectors with the electrical appliances. A terminal is provided inside the connector, and the terminal is usually connected to the wire by means of crimping or welding. Consequently, the resistance at a junction between the terminal and the wire is relatively high. When the current in the wiring harness exceeds the rated current, the junction between the terminal and the wire will generate heat, and in severe cases, will lead to the melting of the connector, resulting in functional failure of the connector and necessitating replacement of either the connector itself or even the entire wiring harness. Moreover, excessive temperature at the terminal-wire junction may even cause a burning accident, resulting in significant personal injury and property damage.

Although fuses are commonly incorporated into wiring harnesses, there is a time delay from the heating of the terminal-wire junction to the blowing of the fuse, which may also cause partial melting of the connector, requiring replacement of the connector or the wiring harness, thus resulting in a waste of costs and maintenance man-hours.

Therefore, in the field of electrical connections, there is an urgent need for a connector that can achieve self-cooling to reduce the temperature when the terminal-wire junction generates heat.

### SUMMARY

The present disclosure provides a self-cooling connector, including a connector housing, a terminal and a conductor which are at least partially disposed in the connector housing, and a cooling device disposed in the connector housing. The terminal is electrically connected to an end of the conductor through a connecting part, and the cooling device is disposed around at least part of an outer periphery of the connecting part. The cooling device includes a rigid shell, and a pressure-applying member and a cooling medium which are disposed in the rigid shell. The cooling medium is made of plastic crystals, which are capable of switching between a disordered state and an ordered state under different pressures. The pressure-applying member is configured to have a property of thermal contraction and cold expansion. When the pressure-applying member is at a normal temperature, it is in an expanded state to apply pressure to the plastic crystals to maintain them in the ordered state. When the pressure-applying member heats up, it contracts to allow the plastic crystals to transition from the ordered state to the disordered state and absorb heat during the transition.

In some embodiments, at least one through cavity is disposed in the connector housing, the terminal and at least part of the conductor are disposed in the cavity, a mounting groove is disposed on the connector housing and at least partially in communication with the cavity, and the cooling device is disposed in the mounting groove.

In some embodiments, the cavity is provided with a thermally conductive material at least at a position of the connecting part, and the thermally conductive material is in contact with the connecting part and the cooling device respectively. The thermally conductive material is one or more selected from the group consisting of one or combinations of thermally conductive silicone grease, a thermally conductive mica sheet, a thermally conductive ceramic sheet and a thermally conductive silicone sheet.

In some embodiments, at least part of the cooling device is inserted into the cavity.

In some embodiments, the connecting part is provided with a heat-dissipating surface, and the cooling device is disposed at a position opposite to the heat-dissipating surface.

In some embodiments, the heat-dissipating surface is attached to the cooling device.

In some embodiments, there are a plurality of the terminals arranged in a single row, the cooling device is plate-shaped and disposed within a side wall of the connector housing, and the distances from the connecting parts to the cooling device are similar or equivalent.

In some embodiments, there are a plurality of the terminals arranged in multiple rows, and the cooling device is annular and sleeved around an outer periphery of the connecting part.

In some embodiments, the connector housing is provided with a cooling cavity between multiple rows of terminals, and the cooling device is plate-shaped and disposed in the cooling cavity.

In some embodiments, a radial clamping groove is disposed on a sidewall of the connecting part, a stopper is disposed on the rigid shell, and when the cooling device is mounted on the connecting part, the stopper is clamped with the clamping groove to prevent the connecting part from disengaging from the connector housing.

In some embodiments, the rigid shell and the connector housing are of an integrated structure, a cooling cavity is disposed on a sidewall of the connector housing at a position corresponding to the connecting part, and the cooling medium and the pressure-applying member are disposed in the cooling cavity.

In some embodiments, the pressure-applying member is made of a thermal-contraction and cold-expansion material, and both the thermal-contraction and cold-expansion material and the plastic crystals are in a particle form and are uniformly mixed and filled in the rigid shell.

In some embodiments, the pressure-applying member and the cooling medium are both sheet-shaped, and are attached and stacked layer by layer within the rigid shell.

In some embodiments, the pressure-applying member is located at a center of the rigid shell, and the cooling medium wraps around the pressure-applying member and fills the rigid shell.

According to some embodiments of the present disclosure, the cooling device is disposed in the connector and filled with the plastic crystals in an ordered state. When the connecting part between the terminal and the wire generates heat, the pressure-applying member heats up and contracts, and the plastic crystals absorb heat during the transition from the ordered state to the disordered state, thereby reducing the temperature of the connector, ensuring that the connector is not melted at the high temperature before the fuse is blown, and avoiding the maintenance or replacement of the connector or the wiring harness. After the fuse is blown, the connecting part between the terminal and the wire returns to the normal temperature, and the pressure-applying member cools and expands, so that the plastic crystals transition from the disordered state to the ordered state while releasing heat. Since the connector does not work at this time, the heat can be released to the mounting environment.

The self-cooling connector of the present disclosure does not require a power supply or a control device. By simply setting the pressure of the pressure-applying member and the temperature point at which the state of the plastic crystals transitions, it can autonomously cool the connector, ensuring safe use of the connector.

According to some embodiments of the present disclosure, the cooling device is integrated with the position retainer for the terminal of the connector, which not only provides cooling for the connector but also secures the terminal in position within the connector, thereby preventing unintentional disengagement of the terminal from the connector.

According to some embodiments of the present disclosure, the cooling devices may be configured in different shapes according to the number and arrangement of the terminals, so as to ensure that the cooling device can absorb heat dissipated from the connecting part between the terminal and the conductor.

Other features and advantages of the present disclosure will become clear from the following detailed description of the exemplary embodiments of the present disclosure made with reference to the drawings.

### BRIEF DESCRIPTION OF THE DRAWINGS

The drawings, which are incorporated in and constitute a part of the specification, illustrate embodiments of the present disclosure and, together with the description, serve to explain the principles of the present disclosure.

FIG. 1 illustrates a schematic diagram of a self-cooling connector according to some embodiments of the present disclosure;

FIG. 2 illustrates a cross-sectional view taken along line A-A in FIG. 1;

FIG. 3 illustrates a cross-sectional view taken from FIG. 1 that includes two terminals arranged side by side;

FIG. 4 illustrates a schematic diagram of a self-cooling connector according to some other embodiments of the present disclosure;

FIG. 5 illustrates a schematic diagram of a self-cooling connector according to some other embodiments of the present disclosure;

FIG. 6 illustrates a cross-sectional view taken along line B-B in FIG. 5;

FIG. 7 illustrates a schematic diagram of a self-cooling connector according to some other embodiments of the present disclosure;

FIG. 8 illustrates a schematic diagram showing the cooperation between a rigid shell and a terminal in FIG. 7;

FIG. 9 illustrates a schematic diagram of a rigid shell in FIG. 7;

FIG. 10 illustrates a schematic diagram of a plurality of the terminals in the present disclosure;

FIG. 11 illustrates a cross-sectional view of a plurality of the terminals in the present disclosure;

FIG. 12(a) illustrates a cross-sectional view of a cooling device according to some embodiments of the present disclosure;

FIG. 12(b) illustrates a cross-sectional view of a cooling device according to some other embodiments of the present disclosure.

### REFERENCE NUMERALS

1: connector housing; 11: terminal; 12: connecting part; 13: conductor; 14: cavity; 15: thermally conductive material; 2: cooling device; 21: rigid shell; 211: stopper; 22: pressure-applying member; 23: cooling medium.

### DETAILED DESCRIPTION OF THE EMBODIMENTS

Various exemplary embodiments of the present disclosure will now be described in detail with reference to the drawings. It should be noted that the relative arrangements, numerical expressions and numerical values of components and steps set forth in these embodiments do not limit the scope of the present disclosure unless otherwise specified.

The following description of at least one exemplary embodiment is merely illustrative in nature and is in no way intended to limit the present disclosure and applications or uses thereof.

Techniques, methods and devices known to those skilled in the art may not be discussed in detail, but should be regarded as part of the specification under appropriate circumstances.

In all examples illustrated and discussed here, any specific value should be interpreted as illustrative only and not as a limitation. Therefore, other examples of the exemplary embodiments may have different values.

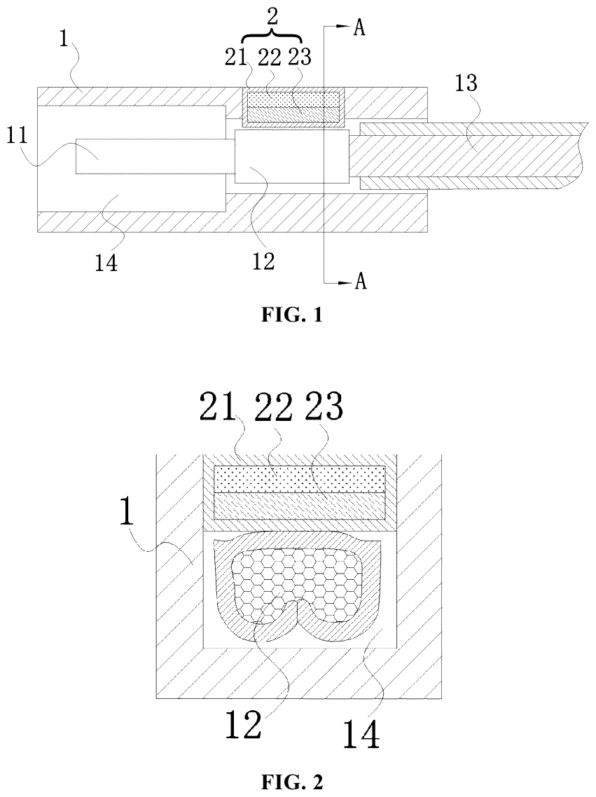

As illustrated in FIG. 1 to FIG. 12(b), the present disclosure provides a self-cooling connector, which includes a connector housing 1, a terminal 11 and a conductor 13 which are at least partially disposed in the connector housing 1, and a cooling device 2 disposed in the connector housing 1. The terminal 11 is electrically connected to an end of the conductor 13 through a connecting part 12, and the cooling device 2 is disposed around at least part of an outer periphery of the connecting part 12. The cooling device 2 includes a rigid shell 21, and a pressure-applying member 22 and a cooling medium 23 which are disposed in the rigid shell 21. The cooling medium 23 is made of plastic crystals, which are capable of switching between a disordered state and an ordered state under different pressures. The pressure-applying member 22 is configured to have a property of thermal contraction and cold expansion. When the pressure-applying member 22 is at a normal temperature, it is in an expanded state to apply pressure to the plastic crystals, so that the plastic crystals are in the ordered state. When the pressure-applying member 22 heats up, it contracts, allowing the plastic crystals to transition from the ordered state to the disordered state and absorb heat during the transition.

In the present disclosure, the cooling device 2 is disposed in the connector housing 1, and includes plastic crystals in the ordered state. When the connecting part 12 between the terminal 11 and the conductor 13 generates heat, the pressure-applying member 22 heats up and contracts, causing the plastic crystals to transition from the ordered state to the disordered state. During this transition process, the plastic crystals absorb heat, thereby reducing the temperature of the connector. This prevents the connector from melting due to high temperature before the fuse blows, thus avoiding the need for repair or replacement of the connector or wiring harness. Under normal conditions, the molecular structure of the plastic crystals exhibits high disorder, that is, its lattice arrangement is irregular. However, even a relatively small applied pressure can induce a change in the lattice structure, enabling a transition between crystalline and amorphous states. As a result, the plastic crystal is highly compressible and reversible, meaning it can return to its original state after compression. When pressure is applied to the plastic crystals, the molecules therein transition from the disordered state to the ordered state. When the applied pressure is reduced, the lattice arrangement of the plastic crystals reverts from the ordered state to the disordered state. During this process, the plastic crystals absorb heat to prevent the temperature of the cooling connecting part 12 from rising, thereby avoiding the connector from being melted or burnt due to excessive temperature.

In some embodiments, at least one through cavity 14 is disposed in the connector housing 1, and the terminal 11 and at least part of the conductor 13 are disposed in the cavity 14. A mounting groove is disposed on the connector housing 1, at least part of the mounting groove is in communication with the cavity 14, and the cooling device 2 is disposed in the mounting groove. As illustrated in FIG. 1, the mounting groove is formed on the connector housing 1 and at least partially in communication with the cavity 14, and the cooling device 2 is disposed in the mounting groove at a position close to the connecting part 12 disposed in the cavity 14.

In some embodiments, the cavity 14 is provided with a thermally conductive material 15 at least at a position of the connecting part 12, and the thermally conductive material 15 is in contact with the connecting part 12 and the cooling device 2 respectively. The thermally conductive material 15 is made of one or more selected from the group consisting of thermally conductive silicone grease, a thermally conductive mica sheet, a thermally conductive ceramic sheet and a thermally conductive silicone sheet. As illustrated in FIG. 4, the thermally conductive material 15 is disposed between the connecting part 12 and the cooling device 2, and two sides of the thermally conductive material 15 are in contact with the connecting part 12 and the cooling device 2 respectively, facilitating efficient heat transfer from the connecting part 12 to the cooling device 2. When the temperature of the connector rises excessively, this arrangement enables the cooling device 2 to cool the connector in time, thereby protecting the internal components of the connector.

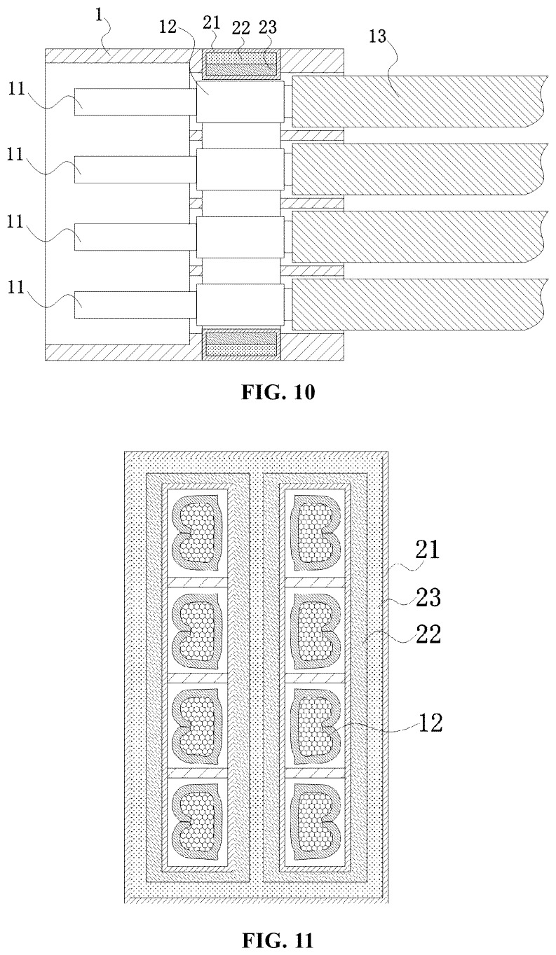

In some embodiments, at least part of the cooling device 2 is inserted into the cavity 14. As illustrated in FIGS. 1 and 10, part of the cooling device 2 is inserted into the cavity 14 so as to be closer to the connecting part 12. This proximity allows for more rapid cooling of the connecting part 12, preventing overheating of the connecting part 12 that could otherwise damage the connector.

In some embodiments, the connecting part 12 is provided with a heat-dissipating surface, and the cooling device 2 is disposed at a position opposite to the heat conducting surface. For example, as illustrated in FIG. 1, an upper surface of the connecting part 12 is the heat-dissipating surface. By disposing the heat-dissipating surface on the connecting part 12, and disposing the cooling device 2 at a position opposite to the heat-dissipating surface, it is convenient to transfer the heat of the connecting part 12 to the cooling device 2, thereby allowing the cooling device 2 to reduce the temperature of the connecting part 12.

In some embodiments, the heat-dissipating surface is attached to the cooling device 2. Further, the cooling device 2 is attached to the heat-dissipating surface of the connecting part 12, which enables the cooling device 2 to promptly reduce the temperature of the connecting part 12 at the moment when the temperature of the connecting part 12 becomes excessively high, thereby protecting the connector.

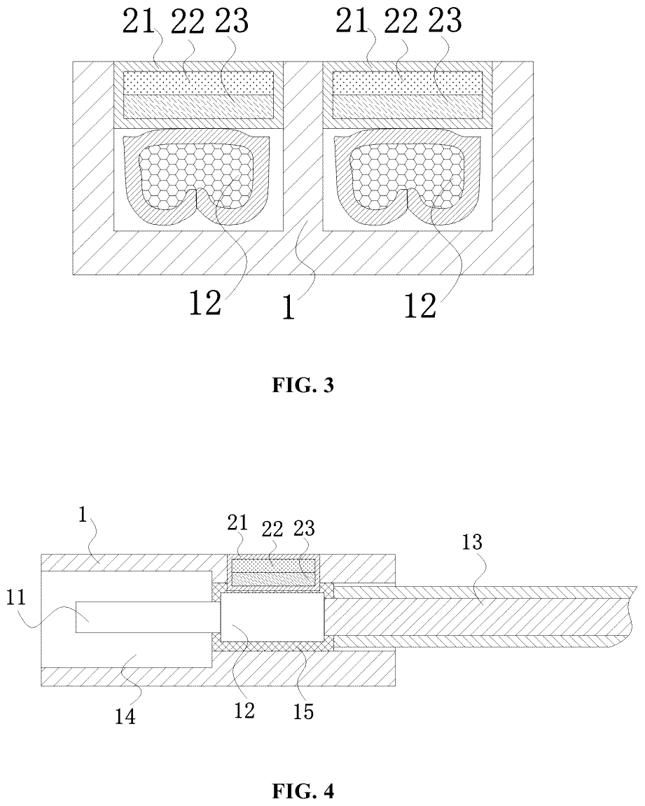

In some embodiments, when a plurality of the terminals 11 are arranged in a single row, the cooling device 2 is plate-shaped and disposed within a side wall of the connector housing 1, and the distances from the connecting parts 12 to the cooling device 2 are similar or equivalent. In some application scenarios, when a plurality of the terminals 11 are arranged in a single row, as illustrated in FIGS. 3 and 4, the cooling device 2 is plate-shaped and disposed within a side wall of the connector housing 1. Each cooling device 2 is disposed close to the corresponding connecting part 12, enabling timely cooling of the connecting parts 12 while also simplifying assembly.

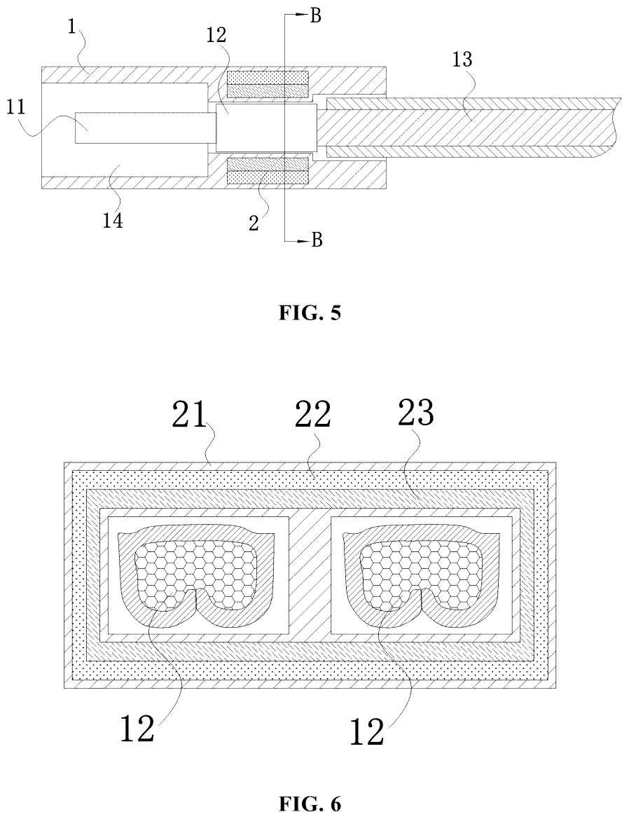

In some embodiments, when a plurality of the terminals 11 are arranged in a single row, the cooling device 2 is annular and sleeved around an outer periphery of the connecting part 12. As illustrated in FIGS. 5 and 6, when there are two terminals arranged in a single row, the distances from the connecting parts 12 to the cooling device 2 is similar or equivalent. In some application scenarios, when a plurality of the terminals 11 are arranged in a single row, the cooling device 2 is in an annular shape and sleeved around the outer periphery of each row of connecting parts 12, thereby ensuring uniform temperature reduction of the connecting parts 12.

In some embodiments, when a plurality of the terminals 11 are arranged in multiple rows, the cooling device 2 is annular and sleeved around the outer periphery of the connecting part 12. As illustrated in FIG. 11, when eight terminals 11 are arranged in two rows, the cooling device 2 is in an annular shape and sleeved around the outer periphery of each row of connecting parts 12. It should be understood that the shape of the cooling devices 2 can be adapted according to the number and arrangement of the terminals 11, ensuring that the cooling device 2 can absorb heat dissipated from the connecting part 12 between the terminal 11 and the conductor 13.

In some embodiments, the connector housing 1 is provided with a cooling cavity between the multiple rows of terminals 11, and the cooling device 2 is plate-shaped and disposed in the cooling cavity. Further, the connector housing 1 is also provided with a cooling cavity between the multiple rows of connecting parts 12. and the plate-shaped cooling device 2 is disposed in the cooling cavity, enabling effective heat dissipation from the region between the multiple rows of connecting parts 12, thereby ensuring that the connector will not be damaged due to the excessive temperature between the multiple rows of connecting parts 12.

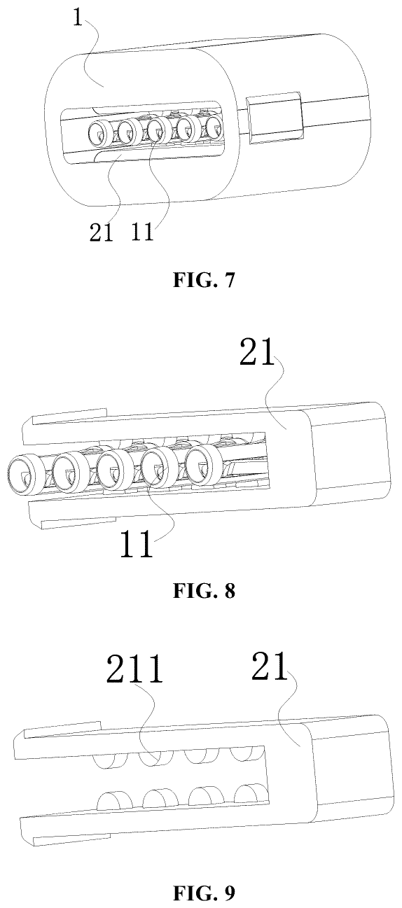

In some embodiments, a radial clamping groove is disposed on a sidewall of the connecting part 12, and a stopper 211 is disposed on the rigid shell 21. When the cooling device 2 is mounted on the connecting part 12, the stopper 211 is clamped with the clamping groove to prevent the connecting part 12 from disengaging from the rigid shell. As illustrated in FIGS. 7 to 9, the clamping groove (not illustrated in the figures) is provided on the sidewall of the connecting part 12, and the stopper 211 is disposed on the rigid shell 21 of the cooling device 2, so that when the cooling device 2 is sleeved around the connecting part 12, the stopper 211 engages with the clamping groove to prevent the connecting part 12 from disengaging from the cooling device 2. The stopper 211 and the clamping groove together form a position retainer for the terminal 11. In the present disclosure, the cooling device 2 is integrated with the position retainer of the connector, which not only reduces the temperature of the connector, but also secures the terminal 11 in its designated in the connector, thereby preventing any unintended disengagement of the terminal 11.

In some embodiments, the rigid shell 21 and the connector housing 1 are of an integrated structure, a cooling cavity (not illustrated in the drawings) is disposed on a sidewall of the connector housing 1 at a position corresponding to the connecting part 12, and the cooling medium 23 and the pressure-applying member 22 are disposed in the cooling cavity. During implementation, the rigid shell 21 and the connector housing 1 are of an integrated structure. The cooling cavity is disposed on the sidewall of the connector housing 1 at the position corresponding to the connecting part 12, and the cooling medium 23 and the pressure-applying member 22 are disposed in the cooling cavity to reduce the temperature of the connecting part 12. The cooling cavity formed on the connector housing 1 serves the function of the rigid shell 21, which simplifies the machining and makes the connector lighter.

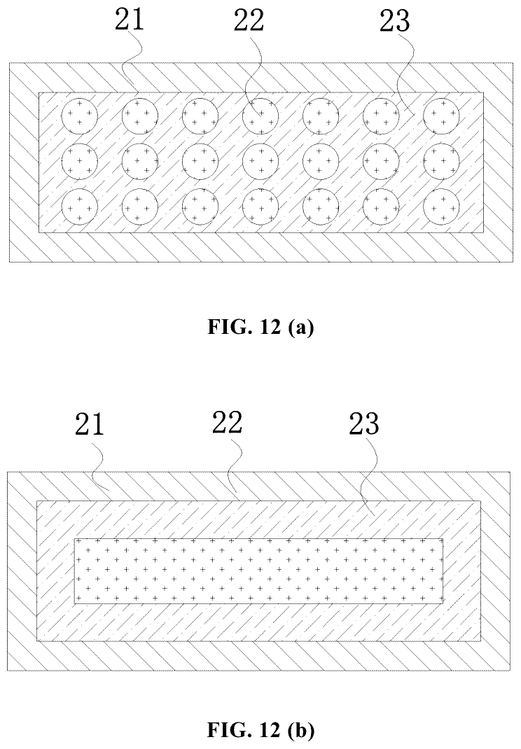

In some embodiments, the pressure-applying member 22 is made of a thermal-contraction and cold-expansion material, and both the thermal-contraction and cold-expansion material and the plastic crystals are in a particle form and are uniformly mixed and filled in the rigid shell 21, as illustrated in FIG. 12(a). The thermal-contraction and cold-expansion material may be antimony, bismuth, gallium, nickel sulfide, gadolinium vanadate, thermal contraction and cold expansion powder of silica aerogel, a gallium-indium alloy, a cross-linked copolymer of N-isopropylacrylamide and N-tert-butylacrylamide, or the like. The thermal-contraction and cold-expansion material is in an expanded state under the normal temperature or low-temperature conditions, but transitions to a contracted state under high-temperature conditions.

Prior to assembling the cooling device 2 with the connector housing 1, the pressure-applying member 22 with the property of thermal contraction and cold expansion and the cooling medium 23 made of plastic crystals are filled into the rigid shell 21 at a high temperature. During the subsequent process of returning to the normal temperature, the pressure-applying member 22 expands to exert compression on the cooling medium 23, causing the plastic crystals to transition from a disordered state to an ordered state. The heat released during this process is dissipated into the surrounding environment. After the cooling device 2 reaches the normal temperature, it is assembled with the connector housing 1. Under normal temperature conditions or when the connector is not in operation, the plastic crystal particles in the cooling device 2 maintain their lattice arrangement in an ordered state due to the compression exerted by the pressure-applying member 22. The pressure-applying member 22, made of the thermal contraction and cold expansion, contracts when the temperature of the connecting part 12 is too high, reducing the pressure on the plastic crystals. As a result, the lattice arrangement of the plastic crystals reverts from the ordered state to the disordered state. During this process, the cooling device 2 absorbs the heat generated by the connecting part 12, thereby achieving the purpose of rapid cooling the connecting part 12.

In some embodiments, the pressure-applying member 22 and the cooling medium 23 are sheet-shaped, and are attached and stacked layer by layer within the rigid shell 21. Generally, the pressure-applying member 22 and the cooling medium 23 are configured as sheets and placed in the rigid shell 21 in a layered and attached manner to simplify the assembly process. Further, as illustrated in FIGS. 2 and 3, the cooling medium 23 is attached to the connecting part 12, and the pressure-applying member 22 is disposed on a side of the cooling medium 23 away from the connecting part 12, achieving the goal of timely and rapid cooling of the connecting part 12.

In some embodiments, the pressure-applying member 22 is located at a center of the rigid shell 21, and the cooling medium 23 wraps around the pressure-applying member 22 and fills the rigid shell 21. During implementation, as illustrated in FIG. 12(b), the pressure-applying member 22 is disposed at the center of the rigid shell 21, and the cooling medium 23 wraps around the outer periphery of the pressure-applying member 22 and fills the rigid shell 21. This arrangement facilitates uniform release of pressure by the pressure-applying member 22. The plastic crystal particles in the cooling device 2 maintain their lattice arrangement in an ordered state due to the compression by the pressure-applying member 22. When the pressure-applying member 22, which is made of a thermal-contraction and cold-expansion material, contracts due to the excessive temperature of the connecting part 12, it uniformly reduces the pressure on the cooling medium 23. Further, this configuration is beneficial for the cooling device 2 to uniformly absorb the heat generated by the connecting part 12, thereby prolonging the service life of the cooling device 2.

Although some specific embodiments of the present disclosure have been described in detail by examples, it should be understood by those skilled in the art that the above examples are only for illustration and are not intended to limit the scope of the present disclosure. It should be understood by those skilled in the art that the above embodiments can be amended without departing from the scope and the spirit of the present disclosure. The scope of the present disclosure is defined by the appended claims.

1. A self-cooling connector, comprising a connector housing, a terminal and a conductor which are at least partially disposed in the connector housing, and a cooling device disposed in the connector housing,
wherein the terminal is electrically connected to an end of the conductor through a connecting part, and the cooling device is disposed around at least part of an outer periphery of the connecting part;
the cooling device comprises a rigid shell, and a pressure-applying member and a cooling medium which are disposed in the rigid shell, wherein the cooling medium is made of plastic crystals, which are capable of switching between a disordered state and an ordered state under different pressures;
the pressure-applying member is configured to have a property of thermal contraction and cold expansion; when the pressure-applying member is at a normal temperature, it is in an expanded state to apply pressure to the plastic crystals to maintain them in the ordered state; and when the pressure-applying member heats up, it contracts to allow the plastic crystals to transition from the ordered state to the disordered state and absorb heat during the transition.

2. The self-cooling connector according to claim 1, wherein at least one through cavity is disposed in the connector housing, the terminal and at least part of the conductor are disposed in the cavity, a mounting groove is disposed on the connector housing and at least partially in communication with the cavity, and the cooling device is disposed in the mounting groove.

3. The self-cooling connector according to claim 2, wherein the cavity is provided with a thermally conductive material at least at a position of the connecting part, and the thermally conductive material is in contact with the connecting part and the cooling device respectively; and
the thermally conductive material is one or more selected from the group consisting of thermally conductive silicone grease, a thermally conductive mica sheet, a thermally conductive ceramic sheet and a thermally conductive silicone sheet.

4. The self-cooling connector according to claim 2, wherein at least part of the cooling device is inserted into the cavity.

5. The self-cooling connector according to claim 2, wherein the connecting part is provided with a heat-dissipating surface, and the cooling device is disposed at a position opposite to the heat-dissipating surface.

6. The self-cooling connector according to claim 5, wherein the heat-dissipating surface is attached to the cooling device.

7. The self-cooling connector according to claim 1, wherein there are a plurality of the terminals arranged in a single row, the cooling device is plate-shaped and disposed within a side wall of the connector housing, and the distances from the connecting parts to the cooling device are similar or equivalent.

8. The self-cooling connector according to claim 1, wherein there are a plurality of the terminals arranged in multiple rows, and the cooling device is annular and sleeved around an outer periphery of the connecting part.

9. The self-cooling connector according to claim 8, wherein the connector housing is provided with a cooling cavity between the multiple rows of terminals, and the cooling device is plate-shaped and disposed in the cooling cavity.

10. The self-cooling connector according to claim 1, wherein a radial clamping groove is disposed on a sidewall of the connecting part, a stopper is disposed on the rigid shell, and when the cooling device is mounted on the connecting part, the stopper is clamped with the clamping groove to prevent the connecting part from disengaging from the connector housing.

11. The self-cooling connector according to claim 1, wherein the rigid shell and the connector housing are of an integrated structure, a cooling cavity is disposed on a sidewall of the connector housing at a position corresponding to the connecting part, and the cooling medium and the pressure-applying member are disposed in the cooling cavity.

12. The self-cooling connector according to claim 1, wherein the pressure-applying member is made of a thermal-contraction and cold-expansion material, and both the thermal-contraction and cold-expansion material and the plastic crystals are in a particle form and are uniformly mixed and filled in the rigid shell.

13. The self-cooling connector according to claim 1, wherein the pressure-applying member and the cooling medium are both sheet-shaped, and are attached and stacked layer by layer within the rigid shell.

14. The self-cooling connector according to claim 1, wherein the pressure-applying member is located at a center of the rigid shell, and the cooling medium wraps around the pressure-applying member and fills the rigid shell.
